(19) United States
(12) Patent Application Publication
(10) Pub. No.: US 2023/0007809 A1
(43) Pub. Date: Jan. 5, 2023

(54) Heat management arrangement, method of manufacturing and electronic device

(71) Applicant: Rohde & Schwarz GmbH & Co. KG, Munchen (DE)

(72) Inventors: Martin Bloss, Munich (DE); Yin Tan, Singapore (SG); Teun Stortelder, Enschede (NL)

(21) Appl. No.: 17/366,365

(22) Filed: Jul. 2, 2021

(51) Int. Cl. H05K 7/20

(52) U.S. Cl. CPC H05K 7/20163; H05K 7/20172; H05K 7/20145; H05K 7/2039

(57) ABSTRACT

The present invention provides a heat management arrangement for an electronic device, in particular for a handheld electronic device. The heat management arrangement comprises an active cooling means comprising a heat sink and at least one airflow channel configured for convective heat transport to an environment by an airflow. Furthermore, the heat management arrangement comprises a passive cooling means configured to be arranged between the heatsink and a surface of the electronic device and comprising a highly heat conductive substance. The passive cooling means is configured to contact the surface of the electronic device and to enhance heat conduction between the surface of the electronic device and the heat sink. In addition or alternatively, the passive cooling means is configured to enhance heat conduction between the surface of the electronic device and the airflow channel. Furthermore, the invention provides a corresponding method of manufacturing such a heat management arrangement on an electronic device and a corresponding electronic device.

### FIELD OF THE INVENTION

The present invention relates to a heat management arrangement for an electronic device, in particular for a handheld electronic device, and to a method of manufacturing such a heat management arrangement on an electronic device. The present invention also relates to a corresponding electronic device comprising such a heat management arrangement.

### BACKGROUND OF THE INVENTION

Even though applicable in general to any electronic device, the present invention and its underlying problem will be hereinafter described in connection with a handheld electronic device having a surface impinged with heat from a heat generating element, such as for example a processor.

In electronic devices and especially in handheld electronic devices having a surface impinged with heat from a heat generating element, cooling of said surface is usually realised by either a passive air cooling system without a fan, or an active air cooling system with a fan.

A passive air cooling system usually comprises a heat sink with high heat conductivity and a large surface, often a ribbed surface, for passive heat transfer by convection to an environmental atmosphere, such as ambient air.

An active air cooling system usually comprises a fan enforcing the convective heat transport via an air stream to an environmental atmosphere.

Other active cooling systems employ a liquid coolant and a floating heat sink with fluid channels. However, this requires a lot more components compared to air cooling systems, such as an additional heat exchanger in order to cool down the liquid coolant to an operation temperature. Thus, liquid cooling systems are usually too heavy and bulky for handheld electronic devices. Furthermore, liquid cooling implies the risk of leakage, which may destroy an electronic device.

### SUMMARY OF THE INVENTION

In view of the above, an object of the present invention is to provide a new and improved heat management system for electronic devices.

In accordance with the present invention, a heat management arrangement for an electronic device as recited in claim 1 and a method of manufacturing a heat management arrangement on an electronic device as recited in claim 11 are provided. Furthermore, an electronic device as recited in claim 18 is provided. Advantageous or preferred features of the invention are recited in the dependent claims.

According to one aspect, therefore, the present invention provides a heat management arrangement for an electronic device, in particular for a handheld electronic device. The heat management arrangement comprises an active cooling means comprising a heat sink and at least one airflow channel configured for convective heat transport to an environment by an airflow. Furthermore, the heat management arrangement comprises a passive cooling means configured to be arranged between the heatsink and a surface of the electronic device and comprising a highly heat conductive substance. The passive cooling means is configured to contact the surface of the electronic device and to enhance heat conduction between the surface of the electronic device and the heat sink. In addition, or alternatively, the passive cooling means is configured to enhance heat conduction between the surface of the electronic device and the airflow channel.

In this way, the invention provides a heat management arrangement which is configured for attachment to a surface impinged with heat from a heat generating element of the electronic device and combines directly active and passive cooling measures which interact in a synergetic way. In particular, the passive cooling means enhances the effectiveness of the active cooling means, and vice versa.

Active cooling is thereby realized by active convection using an airflow through the airflow channel, in particular a forced airflow, e.g. accelerated by a fan. Since the at least one airflow channel and/or at least one corresponding chimney are created in or on the heatsink, the heatsink interacts with both, the airflow of the active cooling means and the highly heat conductive substance of the passive cooling means. The passive cooling is realized by passive convection and/or heat conduction through to a surface for example of an outer housing of the electronic device. Heat transfer to the heatsink and the airflow is enhanced by the highly heat conductive substance. In this way, a thermally highly conductive attachment of the actively cooled heatsink to the outer housing is provided.

On the other hand, the airflow increases a temperature difference between an inner and an outer side of the passive cooling means, such that the heat flow through the highly heat conductive substance is increased.

In an embodiment, the airflow channel is formed as a groove in a surface of the heatsink. In this way, the airflow channel can be easily provided by attaching the heatsink to another surface, especially a surface of the passive cooling means.

In an embodiment, the highly heat conductive substance is a thermal pad. In particular, the thermal pad may be configured soft and conformable. In this way, an effective thermal interface is provided between the heat sink and the surface of the electronic device and surface irregularities can be compensated without increasing thermal resistance. Alternatively or in addition, the highly heat conductive substance may comprise a thermal paste.

In an embodiment, a metal sheet is arranged between the highly heat conductive substance and the surface of the electronic device. For example, the metal sheet can be a copper sheet. This embodiment is particularly advantageous if the highly heat conductive substance is configured as a thermal pad or paste. Accordingly, the metal sheet forms a thermally conductive but mechanically stable barrier, which keeps the thermal pad or paste in shape and/or in place and thus for example prevents the thermal pad or paste to be pressed inside the at least one airflow channel. In this way, a sectional area of the airflow channel is kept constant along the channel and flow resistance is minimized.

In an embodiment, a plurality of airflow channels is provided in the surface of the heatsink. In this way, the convection-active surface of the heatsink is increased and a flow rate of air through the heatsink can be increased.

In an embodiment, the airflow channels are arranged in parallel to each other, at least in a contact area of the passive cooling means. This leads to a more uniform temperature profile in direction transverse to the airflow channels parallel to the surface of the electronic device.

In an embodiment, the active cooling means comprises a chimney fluidically coupled with the airflow channel. For example, the chimney can be configured as a vertical channel section inside the heat sink or as an external chimney coupled to the heat sink. By means of a chimney, the flow rate of an airflow through the airflow channel can be increased by natural convection, which in turn increases the cooling capability of the arrangement.

In an embodiment, the active cooling means comprises a first end and a second end and is configured to establish a thermal gradient between the first end and the second end to create a natural airflow through the at least one airflow channel. The natural airflow is driven by natural convection and can be increased by means of a chimney. In this way, an active fan or pump of the active cooling means is supported by naturally generated airflow.

In an embodiment, the active cooling means comprises an active air flow acceleration element configured to create a forced airflow through the at least one airflow channel. In this way, a predetermined cooling rate is ensured by convection with the forced airflow.

In an embodiment, the at least one airflow channel is oriented in a direction perpendicular to a direction of heat conduction through the passive cooling means. In this way, heat is dissipated from the passive cooling means in the most direct way and effectiveness of the cooling arrangement is increased.

According to another aspect, the invention provides a method of manufacturing a heat management arrangement on an electronic device, comprising the steps of: Arranging a passive cooling means comprising a highly heat conductive substance on a surface of the electronic device such that the passive cooling means is in contact with the surface of the electronic device;

Arranging an active cooling means comprising a heat sink on the surface of the electronic device such that the passive cooling means is arranged between the heatsink and the surface of the electronic device, wherein the active cooling means comprises at least one airflow channel configured for convective heat transport from the heatsink to an environment by an airflow; and

Thermally coupling the passive cooling means and the active cooling means to allow enhanced heat conduction between the surface of the electronic device and the heat sink and/or the airflow channel.

Accordingly, the invention also provides a method of manufacturing a heat management arrangement on a surface of the electronic device, which in use is impinged with heat from a heat generating element of the electronic device. The arrangement can be easily manufactured by attaching a passive cooling means on the surface and arranging an active cooling means thereon in a thermally coupled manner. In this way, active and passive cooling measures can be easily combined, which interact in a synergetic way. By means of the thermal coupling, the passive cooling means enhances the effectiveness of the active cooling means, and vice versa.

In an embodiment, the active cooling means is arranged such that the at least one airflow channel is oriented in a direction substantially parallel to the surface of the electronic device. For example, the airflow channel is formed as a groove in a surface of the heatsink, which is parallel to the surface of the electronic device. This allows a heat transport through the passive cooling means in a direction substantially perpendicular to an airflow direction through the airflow channel, which provides for a most effective heat dissipation.

In an embodiment, the airflow channel is formed as a groove in a surface of the heatsink, wherein the active cooling means is arranged such that the surface of the heatsink is oriented towards the surface of the electronic device. In this way, the groove is closed by a surface of the passive cooling means, particularly the highly conductive material, such that an airflow through the airflow channel can dissipate heat from the highly conductive material by convection.

In an embodiment, the method further comprises a step of arranging a metal sheet between the highly heat conductive substance and the surface of the electronic device. For example, the metal sheet can be a copper sheet. Arranging the metal sheet in between is particularly advantageous if the highly heat conductive substance is configured deformable, for example as a thermal pad or paste. Accordingly, the metal sheet forms a thermally conductive barrier which keeps the thermal pad or paste in place and thus, for example, prevents the thermal pad or paste to be pressed inside the airflow channel. In this way, a sectional area of the airflow channel is kept constant along the channel and flow resistance is minimized.

In an embodiment, the highly heat conductive substance is a thermal pad, which is arranged directly on the surface of the electronic device. In particular, the thermal pad may be configured soft and conformable. In this way, an effective thermal interface is created between the heat sink and the surface of the electronic device. Any surface irregularities can be compensated by the thermal pad without increasing thermal resistance. Alternatively or in addition, the highly heat conductive substance may comprise a thermal paste.

In an embodiment, the active cooling means comprises an active air flow acceleration element and the method comprises a step of arranging the active air flow acceleration element fluidically coupled to the at least one airflow channel, such that a forced airflow through the at least one airflow channel can be created. In this way, a predetermined cooling rate is ensured by convection with the forced airflow.

In an embodiment, the active cooling means is arranged such that the at least one airflow channel is oriented in a direction substantially perpendicular to a direction of heat conduction through the passive cooling means. In this way, heat is dissipated from the passive cooling means in the most direct way and effectiveness of the cooling arrangement is increased.

According to a further aspect, the present invention provides an electronic device. The electronic device comprises a surface impinged with heat from a heat generating element. The electronic device further comprises a heat management arrangement comprising an active cooling means with a heat sink and at least one airflow channel configured for convective heat transport from the heatsink to an environment by an airflow, and a passive cooling means arranged between the heatsink and a surface of the electronic device and comprising a highly heat conductive substance. The passive cooling means is in contact with the surface of the electronic device and configured for enhanced heat conduction between the surface and the heat sink and/or the airflow channel.

As discussed above, the invention is configured for improved heat dissipation, which is realized by combining directly active and passive cooling measures which interact in a synergetic way by thermal coupling. In particular, the passive cooling means enhances the effectiveness of the active cooling means, and vice versa.

Active cooling is thereby realized by active convection using an airflow through the airflow channel, in particular a forced airflow, e.g. accelerated by a fan. Since the at least one airflow channel is created on the heatsink, the heatsink interacts with both, the airflow of the active cooling means and the highly heat conductive substance of the passive cooling means. The passive cooling is realized by internal heat transport from the heat generating element to the surface, e. g. by passive convection and/or heat conduction through to an outer housing of the electronic device which may comprise the surface of the electronic device. The heat transfer from the surface to the heatsink and the airflow is enhanced by the passive heat transport through the highly heat conductive substance. In this way, a thermally highly conductive attachment of the actively cooled heatsink to the outer housing is provided.

The highly heat conductive substance may comprise a thermal pad or paste, as described with regard to the heat management arrangement.

The heat generating element is in particular part of the electronic device.

In an embodiment, the at least one airflow channel is oriented in a direction substantially parallel to the surface of the electronic device. For example, the airflow channel is formed as a groove in a surface of the heatsink, which is parallel to the surface of the electronic device. This allows a heat transport through the passive cooling means in a direction substantially perpendicular to an airflow direction through the airflow channel, which provides for a most effective heat dissipation.

In an embodiment, the airflow channel is formed as a groove in a surface of the heatsink, wherein the surface of the heatsink is oriented facing towards the surface of the electronic device. In this way, the groove is closed by a surface of the passive cooling means, particularly the highly conductive material, such that an airflow through the airflow channel can dissipate heat from the highly conductive material by convection.

The above embodiments can be combined with each other as desired, if useful. Further possible embodiments, further configurations and implementations of the invention also include combinations, not explicitly mentioned, of features of the invention described herein with respect to the embodiments. In particular, the skilled person will thereby also add individual aspects as improvements or additions to the respective basic form of the present invention.

### BRIEF DESCRIPTION OF THE DRAWINGS

For a more comprehensive understanding of the invention and the advantages thereof, exemplary embodiments of the invention are explained in more detail in the following description with reference to the accompanying drawing figures, in which like reference characters designate like parts and in which:

FIG. 1 is a schematic sectional view of a heat management arrangement for an electronic device;

FIG. 2 is a schematic heat flow of an electronic device;

FIG. 3 is a perspective view of an electronic device according to another embodiment; and

FIG. 4 is a perspective view of an electronic device according to yet another embodiment.

The accompanying drawings are included to provide a further understanding of the present invention and are incorporated in and constitute a part of this specification. The drawings illustrate particular embodiments of the invention and together with the description serve to explain the principles of the invention. Other embodiments of the invention and many of the attendant advantages of the invention will be readily appreciated as they become better understood with reference to the following detailed description.

It will be appreciated that common and/or well understood elements that may be useful or necessary in a commercially feasible embodiment are not necessarily depicted in order to facilitate a more abstracted view of the embodiments. The elements of the drawings are not necessarily illustrated to scale relative to each other. It will further be appreciated that certain actions and/or steps in an embodiment of a method may be described or depicted in a particular order of occurrences while those skilled in the art will understand that such specificity with respect to sequence is not actually required. It will also be understood that the terms and expressions used in the present specification have the ordinary meaning as is accorded to such terms and expressions with respect to their corresponding respective areas of inquiry and study, except where specific meanings have otherwise been set forth herein.

### DETAILED DESCRIPTION OF EMBODIMENTS

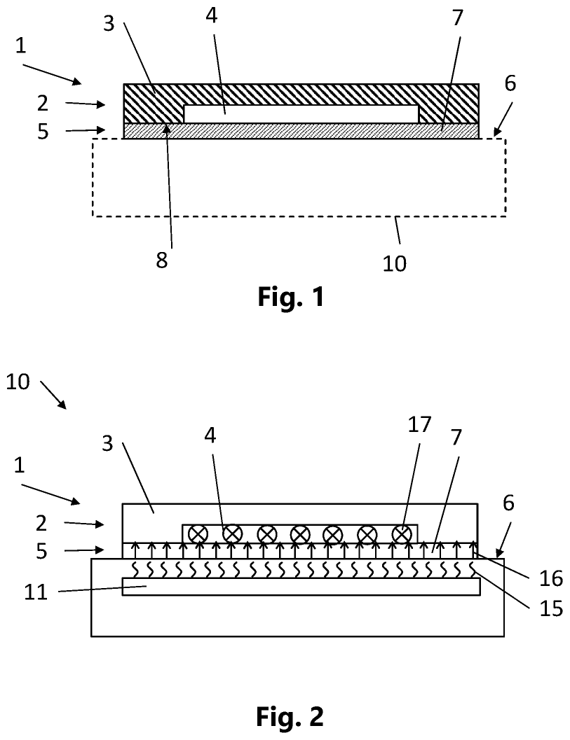

With reference firstly to FIG. 1 of the drawings, a heat management arrangement 1 for an electronic device is illustrated schematically in a sectional view.

The heat management arrangement 1 is for example configured for a handheld electronic device 10, which is schematically symbolised in FIG. 1 by dashed lines. However, the heat management arrangement 1 is not limited to handheld devices and may be applied for example also to standalone electronic devices or other kinds of electronic devices.

The heat management arrangement 1 comprises an active cooling means 2. The active cooling means 2 comprises a heat sink 3, which is, only schematically, symbolized in FIG. 1 by a rectangular block. The heat sink may, for example, comprise a metal body and may have any suitable body form different from such a block. In addition, the heat sink may comprise typical surface enhancing features for heat exchange at outer surfaces, such as lamellas, ribs or the like.

Furthermore, the active cooling means comprises at least one airflow channel 4. The airflow channel 4 is schematically symbolized in FIG. 1 with a rectangular groove in the block, but may have any other suitable form, such as for example a plurality of grooves, one or more rounded grooves, one or more round holes, or other typical channel forms suitable for an airflow channel.

The airflow channel 4 is configured for convective heat transport from the heatsink 3 to an environment by an airflow through the channel. Therefore, the airflow channel 4 is in thermal contact with the heatsink.

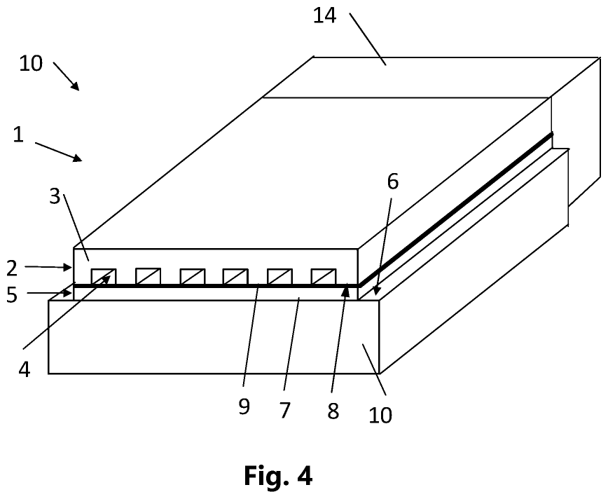

The active cooling means may further comprise a means for moving air (see FIG. 4), in particular an active air flow acceleration element, such as a fan module, for generating an airflow through the airflow channel 4.

The heat management arrangement 1 further comprises a passive cooling means 5. The passive cooling means is configured to be arranged between the heatsink 3 and a surface 6 of the electronic device.

The passive cooling means comprises a highly heat conductive substance 7, such as for example a thermal pad or thermal paste. It is preferably configured to be in direct contact with the surface 6 of the electronic device.

The passive cooling means is further configured for enhanced heat conduction between the surface 6 of the electronic device and the heat sink 3 and/or the airflow channel 4. Accordingly, it is in thermal contact with at least one of the heat sink 3 and the airflow channel 4.

With reference now also to FIG. 2 of the drawings, a schematic heat flow of an electronic device 10 is shown.

The electronic device 10 comprises a surface 6 impinged with heat from a heat generating element 11. The surface may, for example, form part of an outer housing of the electronic device, to which the heat management arrangement of FIG. 1 is attached.

A method of manufacturing such a heat management arrangement on an electronic device therefore comprises a first step of arranging the passive cooling means comprising the highly heat conductive substance on a surface of the electronic device such that the passive cooling means is in contact with the surface of the electronic device. Another step is arranging also the active cooling means comprising the heat sink and the at least one airflow channel on the surface of the electronic device such that the passive cooling means is arranged between the heatsink and the surface of the electronic device. Furthermore, the method comprises the step of thermally coupling the passive cooling means and the active cooling means to allow enhanced heat conduction between the surface of the electronic device and at least one of the heat sink and the airflow channel.

Accordingly, the passive cooling means 5 is in contact with the surface 6 of the electronic device 10 and configured for enhanced heat conduction between the surface 6 and the heat sink 3 and/or the airflow channel 4.

The heat generating element may be for example a CPU (central processing unit), GPU (graphics processing unit) or any other electronic component that in use generates considerable heat.

Heat generated by the heat generating element 11 is transported inside the electronic device to the surface 6 by at least one heat transport mechanism 15 symbolised by waved lines, which comprises at least one of conduction, convection and radiation.

The passive cooling means is in contact with the surface 6, such that the heat is transported from the surface 6 through the passive cooling means by heat conduction 16, symbolized in FIG. 2 by arrows.

The passive cooling means 5 conducts the heat to the heat sink 3 and the airflow channel 4. The airflow channel 4 is formed as a groove in a surface of the heatsink 3. The surface of the heatsink 3 is oriented facing towards the surface 6 of the electronic device 10. This means, in the present example, the at least one airflow channel 4 is oriented in a direction substantially parallel to the surface 6 of the electronic device 10. In this way, the at least one airflow channel 4 is oriented in a direction perpendicular to a direction of heat conduction through the passive cooling means 5.

An airflow through the airflow channel 4 provides for convective heat transport 17 through the channel 4, as symbolized by crosses indicating the flow direction along the channel axis, which is oriented into the drawing plane.

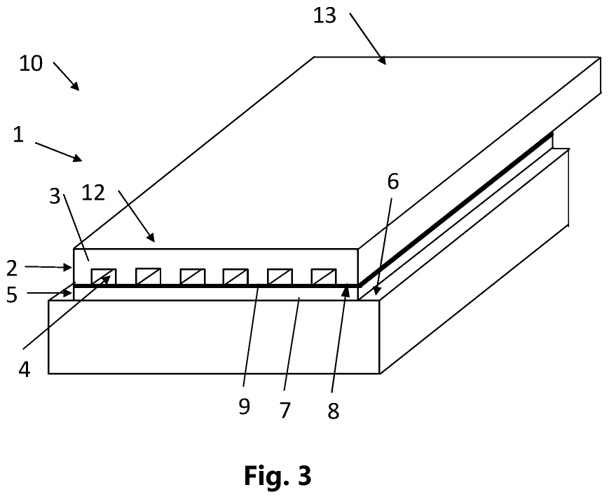

With reference now also to FIG. 3 of the drawings, a perspective view of an electronic device 10 according to a further embodiment is shown.

Again, the heatsink 3 is schematically shown as a rectangular block, but may have any other suitable form. In the depicted example, the active cooling means 2 comprises a plurality of airflow channels 4. Only as an example, six rectangular airflow channels 4 are depicted, which are oriented in parallel to each other. Of course, the number, dimension and form of airflow channels 4 can be any suitable number, dimension and form, depending on the use case.

Similar to the embodiment of FIG. 2, the airflow channels 4 are formed as grooves in a surface 8 of the heatsink 3, which surface 8 is oriented towards the surface 6 of the electronic device 10. Furthermore, the airflow channels 4 are oriented in a direction substantially parallel to the surface 6 of the electronic device 10.

As a difference to FIG. 2, the heat management arrangement 1 additionally comprises a metal sheet 9, which is arranged between the highly heat conductive substance 7 of the passive cooling means 5 and the surface 8 of the heat sink 3 and the channels 4 of the active cooling means 2. The highly heat conductive substance 7 is configured as a thermal pad and the metal sheet 9 is configured as a copper sheet. Therefore, a high heat exchange rate of the highly heat conductive substance 7 with the heat sink 3 and the airflow channels 4 is provided due to low thermal resistance. On the other hand, the shape of the thermal pad is maintained even, despite the grooved surface attached thereto. This is achieved by the copper sheet, which prevents the thermal pad from being locally squeezed or pressed into the airflow channels 4.

In manufacturing such a heat management arrangement 10, a step of arranging the metal sheet 9 between the highly heat conductive substance 7 and the surface 8 of the electronic device 1 is additionally provided.

The active cooling means 2 comprises a first end 12 and a second end 13, between which the airflow channels 4 extend. The active cooling means 2 at the second end 13 extends beyond the passive cooling means 5. In this way, it is configured to establish a thermal gradient between the first end 12 and the second end 13. Of course, in other embodiments, also other measures would be possible to establish a thermal gradient, such as additional cooling measures or the like.

The thermal gradient creates a natural airflow through the at least one airflow channel 4. Especially, this effect can be enhanced by providing a chimney at one end, which is fluidically coupled with the airflow channels.

Finally, referring to FIG. 4 of the drawings, a perspective view of an electronic device according to another embodiment is shown.

According to this embodiment, the active cooling means 2 comprises an active air flow acceleration element 14. This is schematically symbolized by a rectangular block and may, for example, be formed as a fan module and comprise a fan for propelling air.

The air flow acceleration element 14 is fluidically coupled to the airflow channels 4. In this way, a forced airflow through the airflow channels 4 is created.

In manufacturing such a heat management arrangement, an additional step of arranging the active air flow acceleration element fluidically coupled to the airflow channels is provided such that a forced airflow through the at least one airflow channel can be created.

Although specific embodiments of the invention are illustrated and described herein, it will be appreciated by those of ordinary skill in the art that a variety of alternate and/or equivalent implementations exist. It should be appreciated that the exemplary embodiment or exemplary embodiments are examples only and are not intended to limit the scope, applicability, or configuration in any way. Rather, the foregoing summary and detailed description will provide those skilled in the art with a convenient road map for implementing at least one exemplary embodiment, it being understood that various changes may be made in the function and arrangement of elements described in an exemplary embodiment without departing from the scope as set forth in the appended claims and their legal equivalents. Generally, this application is intended to cover any adaptations or variations of the specific embodiments discussed herein.

It will also be appreciated that in this document the terms “comprise”, “comprising”, “include”, “including”, “contain”, “containing”, “have”, “having”, and any variations thereof, are intended to be understood in an inclusive sense, such that the process, method, device, apparatus or system described herein is not limited to those features or parts or elements or steps recited but may include other elements, features, parts or steps not expressly listed or inherent to such process, method, article, or apparatus. Furthermore, the terms “a” and “an” used herein are intended to be understood as meaning one or more unless explicitly stated otherwise. Moreover, the terms “first”, “second”, “third”, etc. are used merely as labels, and are not intended to impose numerical requirements on or to establish a certain ranking of importance of their objects.

### LIST OF REFERENCE SIGNS

1 heat management arrangement
2 active cooling means
3 heat sink
4 airflow channel
5 passive cooling means
6 surface
7 highly heat conductive substance
8 surface
9 metal sheet
10 electronic device
11 heat generating element
12 first end
13 second end
14 air flow acceleration element
15 heat transport mechanism
16 heat conduction
17 convective heat transport

1. A heat management arrangement for an electronic device, comprising:
an active cooling means comprising a heat sink and at least one airflow channel configured for convective heat transport to an environment by an airflow, and
a passive cooling means configured to be arranged between the heatsink and a surface of the electronic device and comprising a highly heat conductive substance,
wherein the passive cooling means is configured to contact the surface of the electronic device and to enhance heat conduction between the surface of the electronic device and the heat sink and/or the airflow channel.

2. The arrangement of claim 1, wherein the airflow channel is formed as a groove in a surface of the heatsink.

3. The arrangement of claim 1, wherein a metal sheet is arranged between the highly heat conductive substance and the surface of the electronic device.

4. The arrangement of claim 1, wherein a plurality of airflow channels is provided in the surface of the heatsink.

5. The arrangement of claim 4, wherein the airflow channels are arranged in parallel to each other, at least in a contact area of the passive cooling means.

6. The arrangement of claim 1, wherein the highly heat conductive substance is a thermal pad.

7. The arrangement of claim 1, wherein the active cooling means comprises a chimney fluidically coupled with the airflow channel.

8. The arrangement of claim 1, wherein the active cooling means comprises a first end and a second end and is configured to establish a thermal gradient between the first end and the second end to create a natural airflow through the at least one airflow channel.

9. The arrangement of claim 1, wherein the active cooling means comprises an active air flow acceleration element configured to create a forced airflow through the at least one airflow channel.

10. The arrangement of claim 1, wherein the at least one airflow channel is oriented in a direction perpendicular to a direction of heat conduction through the passive cooling means.

11. A method of manufacturing a heat management arrangement on an electronic device, comprising the steps of:
Arranging a passive cooling means comprising a highly heat conductive substance on a surface of the electronic device such that the passive cooling means is in contact with the surface of the electronic device;
Arranging an active cooling means comprising a heat sink on the surface of the electronic device such that the passive cooling means is arranged between the heatsink and the surface of the electronic device, wherein the active cooling means comprises at least one airflow channel configured for convective heat transport from the heatsink to an environment by an airflow; and
Thermally coupling the passive cooling means and the active cooling means to allow enhanced heat conduction between the surface of the electronic device and the heat sink and/or the airflow channel.

12. The method of claim 11, wherein the active cooling means is arranged such that the at least one airflow channel is oriented in a direction substantially parallel to the surface of the electronic device.

13. The method of claim 11, wherein the airflow channel is formed as a groove in a surface of the heatsink, wherein the active cooling means is arranged such that the surface of the heatsink is oriented towards the surface of the electronic device.

14. The method of claim 13, further comprising a step of arranging a metal sheet between the highly heat conductive substance and the surface of the electronic device.

15. The method of claim 11, wherein the highly heat conductive substance is a thermal pad, which is arranged directly on the surface of the electronic device.

16. The method of claim 11, wherein the active cooling means comprises an active air flow acceleration element and the method comprises a step of arranging the active air flow acceleration element fluidically coupled to the at least one airflow channel, such that a forced airflow through the at least one airflow channel can be created.

17. The method of claim 11, wherein the active cooling means is arranged such that the at least one airflow channel is oriented in a direction substantially perpendicular to a direction of heat conduction through the passive cooling means.

18. An electronic device, comprising:
a surface impinged with heat from a heat generating element;
a heat management arrangement comprising an active cooling means with a heat sink and at least one airflow channel configured for convective heat transport from the heatsink to an environment by an airflow, and a passive cooling means arranged between the heatsink and a surface of the electronic device and comprising a highly heat conductive substance,
wherein the passive cooling means is in contact with the surface of the electronic device and configured for enhanced heat conduction between the surface and the heat sink and/or the airflow channel.

19. The device of claim 18, wherein the at least one airflow channel is oriented in a direction substantially parallel to the surface of the electronic device.

20. The device of claim 18, wherein the at least one airflow channel is formed as a groove in a surface of the heatsink, wherein the surface of the heatsink is oriented facing towards the surface of the electronic device.
